(19) United States
(12) Patent Application Publication
(10) Pub. No.: US 2014/0014164 A1
(43) Pub. Date: Jan. 16, 2014

(54) CONNECTING STRUCTURE OF SOLAR CELL MODULES

(71) Applicant: SAMSUNG SDI CO., LTD., Yongin-si (KR)

(72) Inventors: Nam-Kyu Song, Yongin-si (KR); Jong-Hwan Kim, Yongin-si (KR); Yong-Hee Park, Yongin-si (KR); June-Hyuk Jung, Yongin-si (KR)

(21) Appl. No.: 13/831,097

(22) Filed: Mar. 14, 2013

Related U.S. Application Data
(60) Provisional application No. 61/670,975, filed on Jul. 12, 2012.

(51) Int. Cl. H01L 31/05; F16B 5/00

(52) U.S. Cl. CPC H01L 31/05; F16B 5/0052
USPC 136/251; 403/294

(57) ABSTRACT

A solar cell array includes a number of solar cell modules, each of the solar cell modules including a frame having a first side extending along a first direction, and a first insertion hole is formed in the first side and extending along the first direction. The solar cell array also includes a connecting structure extending along a second direction perpendicular to the first direction for connecting two adjacent modules of the solar cell modules, and the connecting structure includes a first coupling portion and a second coupling portion respectively received in the first insertion holes of the two adjacent modules, wherein each of the first insertion holes has a guide portion and an insertion portion, the guide portion bending from the insertion portion to guide the first coupling portion and the second coupling portion into the respective guide portions.

### CROSS-REFERENCE TO RELATED APPLICATION

This application claims priority to and the benefit of U.S. Provisional Application No. 61/670,975, filed on Jul. 12, 2012, in the U.S. Patent and Trademark Office, the entire content of which is incorporated herein by reference.

### BACKGROUND

1. Technical Field

One or more embodiments of the present invention relate to connecting structures of solar cell modules and alignment of the solar cell modules.

2. Related Art

Recently, as the eventual exhaustion of energy sources such as oil or coal is expected, interests in substitute (alternative) energy sources are increasing. Among these energy sources, solar cells are batteries that convert solar energy directly into electrical energy by using a semiconductor device and are regarded as a next-generation battery.

A solar cell converts light energy into electrical energy by using the photovoltaic effect, and may be classified according to materials, for example, into a silicon solar cell, a thin film solar cell, a dye-sensitized solar cell, and an organic polymer solar cell.

A solar generator includes an array formed by connecting a plurality of solar cell modules in which solar cells are connected serially or in parallel. According to the related art, screw holes are processed or provided in the frames of the solar cell modules, and, for example, a connection plate in which assembly holes corresponding to the screw holes are formed, is disposed between adjacent solar cell modules. Then, the plurality of solar cell modules are connected to form an array, in which the assembly holes and the screw holes are assembled together by screws. However, according to this method, it is difficult to form the screw holes, and if the screw holes and the assembly holes do not match up with each other, it is difficult to align the plurality of solar cell modules with one another.

### SUMMARY

Aspects of one or more embodiments of the present invention are directed toward a connecting structure of solar cell modules in which connection of the solar cell modules and alignment of the solar cell modules may be easily performed. In one embodiment, a solar cell array includes a plurality of solar cell modules, each of the solar cell modules including: a frame having a first side extending along a first direction, and a first insertion hole formed in the first side and extending along the first direction; and a connecting structure extending along a second direction perpendicular to the first direction for connecting two adjacent modules of the solar cell modules, and including a first coupling portion and a second coupling portion respectively received in the first insertion holes of the two adjacent modules, wherein each of the first insertion holes has a guide portion and an insertion portion, the guide portion bending from the insertion portion to guide the first coupling portion and the second coupling portion into the respective guide portions.

The connecting structure may have a half dumbbell shape.

Each of the first coupling portion and the second coupling portion may have a hemispheric shape.

The connecting structure may further include a middle portion connected between the first coupling portion and the second coupling portion of the connecting structure.

The insertion portion may extend along the first direction to the guide portion, and the guide portion may have a larger width than that of the insertion portion in a third direction perpendicular to both the first direction and the second direction.

The guide portion may have a shape corresponding to the first coupling portion or the second coupling portion such that the connecting structure is rotatable in the guide portion.

A side of the guide portion may have a curvature substantially identical to that of the first coupling portion or the second coupling portion.

A side of the guide portion may include a first securing part configured to secure the first coupling portion or the second coupling portion in the corresponding guide portion.

At least one of the first coupling portion or the second coupling portion may include a second securing part configured to engage the first securing part.

At least one of the first securing part or the second securing part may be substantially elastic.

One of the first securing part or the second securing part may include a groove or step, and another one of the first securing part or the second securing part may include a protrusion.

The insertion portion may include a plurality of insertion portions extending along the first direction, and the guide portion may include a plurality of guide portions, the insertion portions and the guide portions being alternately arranged, and each of the guide portions may have a larger width than that of a corresponding one of the insertion portions in a third direction perpendicular to both the first direction and the second direction.

The frame may further include a second side extending from an end of the first side in the second direction, and a portion of the first insertion hole extends into the second side in the second direction.

A solar cell module of the plurality of solar cell modules may further include a second insertion hole extending along the second side of the frame.

The first insertion holes of the two adjacent modules may face each other in the second direction and may be substantially symmetrical in shape with respect to each other.

In one embodiment, a connecting structure for connecting adjacent solar cell modules is provided. The connecting structure includes a first coupling portion, a second coupling portion, and a middle portion extending along a first direction and having a first end and a second end respectively connected to the first coupling portion and the second coupling portion. Widths of the first coupling portion and the second coupling portion are wider than that of the middle portion in a second direction perpendicular to the first direction. A cross-section of each of the first coupling portion and the second coupling portion has a curved side and a substantially straight side, the first direction being normal to the cross-section. The connecting structure is configured to be rotatable around an axis extending along the first direction when the first coupling portion and the second coupling portion are respectively received in insertion holes of the adjacent solar cell modules.

The connecting structure may have a half dumbbell shape.

Each of the first coupling portion and the second coupling portion may have a hemispheric shape.

A cross-section of the middle portion may have a rectangular, circular, or semi-circular shape.

Each of the first coupling portion and the second coupling portion may have a shape corresponding to a guide portion of the insertion hole such that the connecting structure is rotatable in the guide portion around the axis extending along the first direction, while the connecting structure is not substantially rotatable in another portion of the insertion hole.

The curved side may have a curvature substantially identical to that of a side of the guide portion of the insertion hole.

At least one of the first coupling portion or the second coupling portion may include a first securing part configured to engage a second securing part on a side of the guide portion of the insertion hole.

At least one of the first securing part or the second securing part may be substantially elastic.

One of the first securing part or the second securing part may include a groove or step, and another one of the first securing part or the second securing part may include a protrusion.

Each of the first coupling portion and the second coupling portion may have a semi-cylindrical shape.

Each of the first coupling portion and the second coupling portion may have two semi-cylindrical portions spaced apart from each other in the first direction.

The curved side may have at least two sections having different curvatures.

A cross section of each of the first coupling portion and the second coupling portion in the first direction, may have a tapered shape.

According to the embodiments of the present invention, solar cell modules may be easily connected and aligned.

### BRIEF DESCRIPTION OF THE DRAWINGS

FIG. 1A is a schematic perspective view of a connecting structure for connecting solar cell modules according to an embodiment of the present invention;

FIG. 1B is a schematic perspective view of a solar cell module according to an embodiment of the present invention;

FIG. 2 is an exploded perspective view of a solar cell unit of FIG. 1A;

FIG. 3 illustrates a connection member illustrated in FIG. 1A according to an embodiment of the present invention;

FIG. 4 is a cross-sectional view of the solar cell module of FIG. 1A cut along a line I-I′;

FIGS. 5A through 5C illustrate a method of connecting solar cell modules using the connecting structure of FIG. 1A according to an embodiment of the present invention;

FIG. 6A is a modification example of a connecting structure of the solar cell modules of FIG. 1A according to an embodiment of the present invention;

FIG. 6B is a modification example of a connecting structure of the solar cell modules of FIG. 1A according to an embodiment of the present invention;

FIG. 7 is another modification example of a connecting structure of the solar cell modules of FIG. 1A according to an embodiment of the present invention; and

FIGS. 8 through 11 illustrate different connection members according to several embodiments of the present invention.

### DESCRIPTION OF EMBODIMENTS

In the drawings, each constituent element may be exaggerated, omitted, or schematically illustrated for convenience of explanation and clarity. Also, the size of each constituent element may not perfectly reflect an actual size. In the present specification, when a first constituent element is described as being formed “on” or “under” a second constituent element, the first constituent element may be formed “directly” or “indirectly” “on” or “under” the second constituent element with or without a third constituent element interposed therebetween. The state of being “on” or “under” a constituent element is described based on the drawings. In addition, like elements are labeled with like reference numerals even when illustrated in different drawings.

The present invention will now be described more fully with reference to the accompanying drawings, in which exemplary embodiments of the invention are shown.

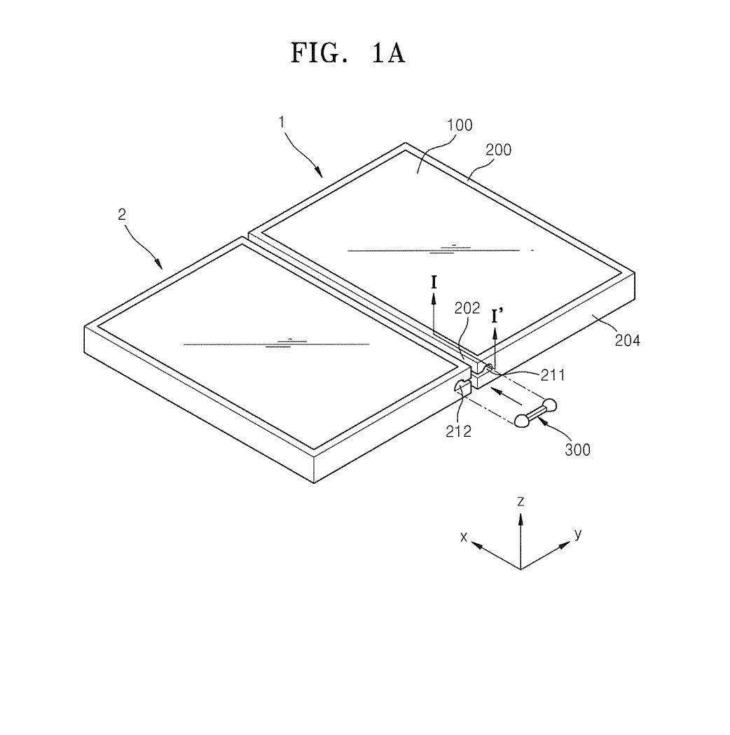

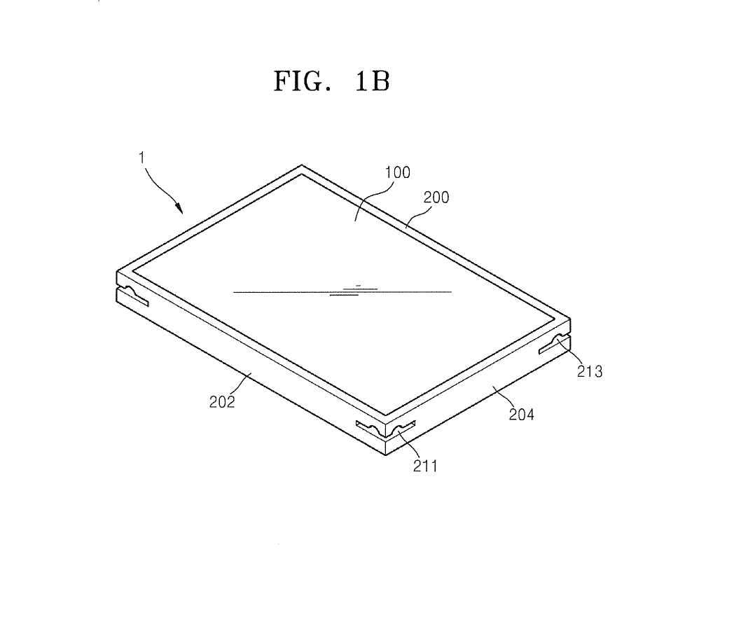

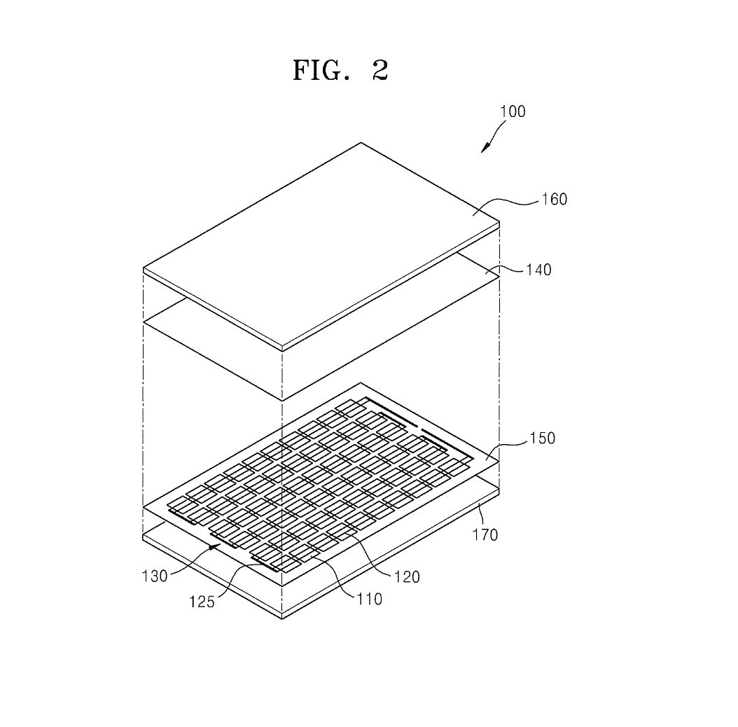

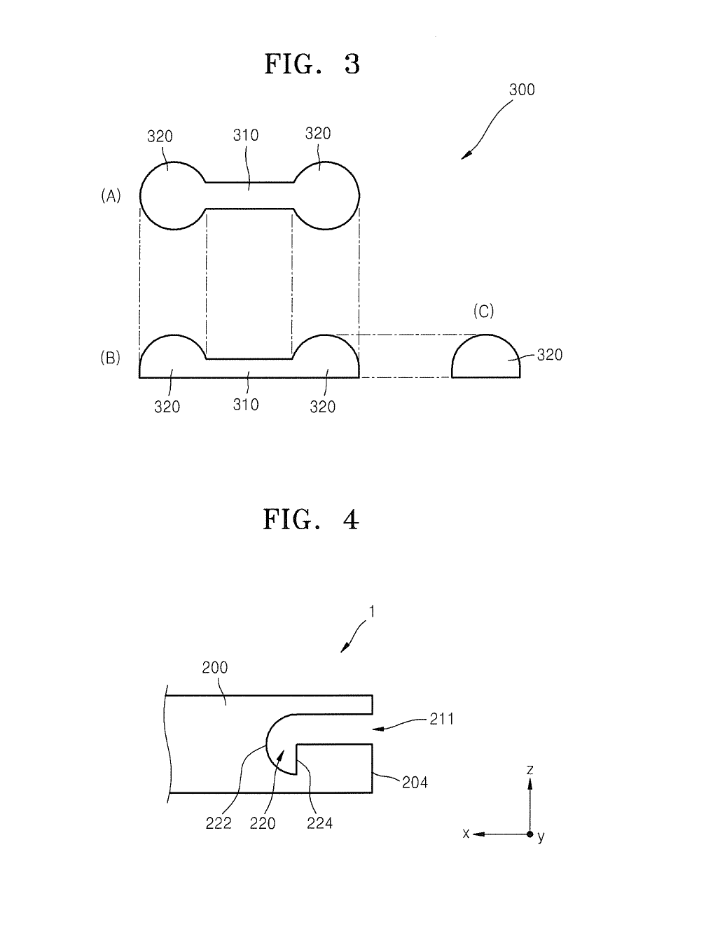

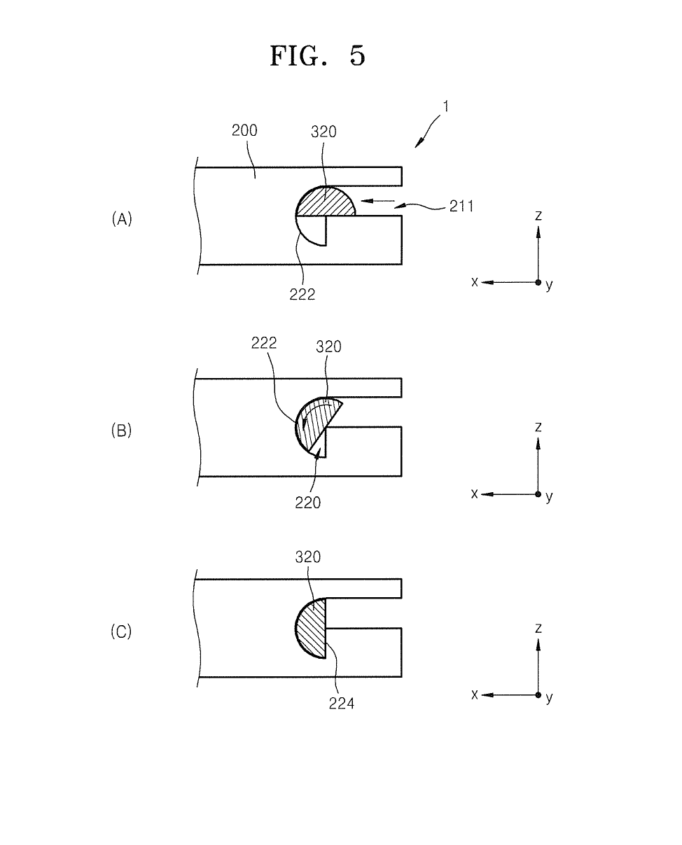

FIG. 1A is a schematic view of a connecting structure for connecting solar cell modules according to an embodiment of the present invention. FIG. 2 is an exploded perspective view of a solar cell unit 100 of FIG. 1A. FIG. 3 illustrates a connection member 300 illustrated in FIG. 1A according to an embodiment of the present invention. FIG. 4 is a cross-sectional view of the solar cell unit 100 of FIG. 1A cut along a line I-I′. FIGS. 5A through 5C illustrate a method of connecting solar cell modules using the connecting structure of FIG. 1A.

Referring to FIG. 1A, in the connecting structure of solar cell modules, a first solar cell module 1 and a second solar cell module 2, which are disposed adjacent to each other, are connected to each other. The first solar cell module 1 and the second solar cell module 2 may be connected by inserting the connection member 300 into a first insertion hole 211 formed in the first solar cell module 1 and a second insertion hole 212 formed in the second solar cell module 2.

First, the first solar cell module 1 and the second solar cell module 2 may have the same shape, e.g., rectangular shape, and are placed on a holder (not shown) or the like and connected to one another to form an array.

Each of the first solar cell module 1 and the second solar cell module 2 includes a solar cell unit 100 and a frame 200 connected to a boundary or periphery of the solar cell unit 100. As the first solar cell module 1 and the second solar cell module 2 have the same shape, description will focus on the first solar cell module 1 below. Also, the first solar cell module 1 will be described with respect to a first direction x, a second direction y that is perpendicular to the first direction x, and a third direction z that is perpendicular to the first direction x and the second direction y. The first direction x may be a height direction of the first solar cell module 1, the second direction y may be a width direction of the first solar cell module 1, and the third direction z may be a thickness direction of the first solar cell module 1.

As illustrated in FIG. 2, the solar cell unit 100 may include a plurality of solar cells 110, a plurality of ribbons 120 that form a plurality of solar cell strings 130 by electrically connecting the plurality of solar cells 110, a first encapsulation film 140 and a front substrate 160 that are disposed above the plurality of solar cells 110, and a second encapsulation film 150 and a rear substrate 170 that are disposed below the plurality of solar cells 110.

Each of the solar cells 110 is a semiconductor device that converts solar energy into electrical energy, and may be, for example, a silicon solar cell, a compound semiconductor solar cell, a dye-sensitized solar cell, or a tandem solar cell.

The ribbons 120 electrically connect the plurality of solar cells 110 serially, in parallel, or in combination of serial and parallel connections to form the solar cell strings 130. In one embodiment, the ribbons 120 may connect a front electrode formed on a light receiving surface of the solar cell 110 and a rear electrode formed on a rear surface of another adjacent solar cell 110 by using a tabbing operation. The tabbing operation may be performed by coating a surface of the solar cells 110 with a flux, disposing the ribbons 120 on the solar cells 110 coated with the flux, and performing heat treatment. Alternatively, a conductive film may be attached between a surface of the solar cells 110 and the ribbons 120, and then the plurality of solar cells 110 may be connected in series or in parallel by thermal compression.

Here, the solar cell strings 130 may be electrically connected to one another via bus ribbons 125. In one embodiment, the bus ribbons 125 are arranged horizontally at two ends of the solar cell strings 130, and the two ends of the ribbons 120 of the solar cell strings 130 may be alternately connected by the bus ribbons 125. Also, the bus ribbons 125 may be connected to a junction box which is disposed on a rear surface of the solar cell unit 100.

The first encapsulation film 140 is disposed on the light receiving surface of the solar cells 110, and the second encapsulation film 150 is disposed on a rear surface of the solar cells 110. The first encapsulation film 140 and the second encapsulation film 150 are adhered by lamination to block water or oxygen penetration which may adversely affect the solar cells 110.

The first encapsulation film 140 and the second encapsulation film 150 may be formed of, for example, an ethylene vinyl acetate (EVA) copolymer, a polyvinyl butyral, an oxide of ethylene vinyl acetate, a silicon resin, an ester resin, or an olefin resin.

The front substrate 160 is disposed on the first encapsulation film 140 and may be formed of a highly light transmissive glass or a polymer material. Also, to protect the solar cells 110 from external impact, the front substrate 160 may be formed of tempered glass. In order to prevent or reduce reflection of solar light and to increase transmittance of solar light, the front substrate 160 may be formed of low-iron tempered glass of a low iron content.

The rear substrate 170 is a layer protecting the solar cells 110 on the rear surface of the solar cell 110, and performs functions such as water proofing, insulation, and ultraviolet (UV) blocking. The rear substrate 170 may be a stacked structure of polyvinyl fluoride/PET/polyvinyl fluoride, but is not limited thereto.

While the solar cell unit 100 including the solar cells 110 that are crystalline, has been described above, the solar cell unit 100 is not limited thereto, and the solar cell unit 100 may include a thin film type solar cell, a dye-sensitized solar cell, or an organic polymer type solar cell.

Referring back to FIG. 1A, the frame 200 is connected to the boundary of the solar cell unit 100, and the first insertion hole 211 is formed in the frame 200.

The first insertion hole 211 may be formed in the frame 200 of the first solar cell module 1 along a first surface 202. In one embodiment, the first insertion hole 211 is a groove having a portion that extends from the first surface 202 of the frame 200 to a set or predetermined depth in the second direction y of the first solar cell module 1, and another portion that passes through a second surface 204 (that is perpendicular to the first surface 202) and is formed to extend along the first direction x of the first solar cell module 1.

Also, a height of the first insertion hole 211 corresponds to the third direction z of the first solar cell module 1, and the first insertion hole 211 may extend along the second direction y of the first solar cell module 1 from the first surface 202 of the frame 200 at a set or predetermined height and may have a hemispheric shape at an internal end thereof. The shape of the first insertion hole 211 corresponds to a shape of the connection member 300 (e.g., see FIG. 3) which will be described later with reference to FIG. 3.

Here, the second insertion hole 212 formed in the second solar cell module 2 adjacent to the first solar cell module 1 is formed symmetrically to the first insertion hole 211 described above with respect to the first direction x of the first solar cell module 1. As the connection member 300 is inserted simultaneously or concurrently into both the first insertion hole 211 and the second insertion hole 212, the first solar cell module 1 and the second solar cell module 2 may be connected to each other by the connection member 300.

FIG. 1B is a schematic perspective view of a solar cell module according to an embodiment of the present invention. Referring to FIG. 1B, a third insertion hole 213 may be further formed along the second surface 204. Accordingly, the first solar cell module 1 may be connected to a third solar cell module (not shown) not only in the second direction y but also in the first direction x.

FIG. 3 is a plan view (A), a front view (B), and a side view (C) of the connection member 300 according to an embodiment of the present invention. Referring to FIG. 3, the connection member 300 includes two coupling portions 320 and a connection portion 310 connecting the two coupling portions 320 to each other.

The two coupling portions 320 are hemisphere-shaped, and are respectively inserted into the first insertion hole 211 and the second insertion hole 212. When the two coupling portions 320 are inserted into the first insertion hole 211 and the second insertion hole 212, the connection portion 310 may be fixed in the insertion holes 211 and 212 such that the first solar cell module 1 and the second solar cell module 2 are not separated from each other. A cross-section of the connection portion 310 may be rectangular, circular, or semicircle-shaped, but is not limited thereto.

Here, FIG. 4 is a cross-sectional view of the first solar cell module 1 of FIG. 1A cut along a line I-I′, illustrating a detailed view of the first insertion hole 211. Referring to FIG. 4, the first insertion hole 211 formed through the second surface 204 along the first direction x of the first solar cell module 1 extends up to a receiving portion 220.

The receiving portion 220 is an area where the coupling portion 320 (see FIG. 3) inserted into the first insertion hole 211 is received, and the receiving portion 220 extends along the first direction x of the first solar cell module 1 and is bent downward at 90°. For example, the first insertion hole 211 and the receiving portion 220 are connected together to form an L-shape opening.

The receiving portion 220 includes a guide portion 222 that is curved and a suspension threshold 224 formed along the third direction z of the first solar cell module 1. The guide portion 222 allows the first insertion hole 211 and the receiving portion 220 to be formed continuously, and has the same or substantially the same curvature radius as the hemisphere-shape of the coupling portion 320 (see FIG. 3) and is convex in an insertion direction of the coupling portion 320.

The guide portion 222 has a concave surface. The concave surface may be partly circular in cross-section. In a preferred embodiment the partly circular cross-section is across an axis extending substantially perpendicular to an insertion direction and an axis along said insertion direction, preferably the cross-section is across axes x and z. The term partly-circular may be preferably an arc of a circle from 75° to 180°, preferably 90° to 180°, more preferably 125° to 180°, more preferably 140° to 180°.

Also, the concave surface may be partly spherical or cylindrical. The term partly spherical or cylindrical preferably means that the concave surface would cover 25% to 55% of a sphere of the same radius as the receiving portion 220, preferably 35% to 55%, more preferably 40% to 50%.

Also, the suspension threshold 224 contacts a lower surface of the coupling portion 320 when the coupling portion 320 is received in the receiving portion 220. The suspension threshold 224 may prevent the coupling portion 320 received in the receiving portion 220 from being separated from the first solar cell module 1.

A method of connecting solar cell modules using the connecting structure of FIG. 1A will be described with reference to FIG. 5. Hereinafter, for convenience of description, an operation of using the coupling portions 320 to connect the solar cell modules will be illustrated and described.

The solar cell modules are connected using a connecting structure as follows: first, as illustrated in (A) of FIG. 5, the coupling portion 320 is inserted into the first insertion hole 211, and then moves along the first direction x of the first solar cell module 1 so as to meet the guide portion 222.

Here, the guide portion 222 has a uniform curvature radius so as to have the same shape as the coupling portion 320, and thus, if force is continuously applied to the coupling portion 320 in the first direction x of the first solar cell module 1, as illustrated in (B) of FIG. 5, the coupling portion 320 rotates in a direction perpendicular to the first direction x of the first solar cell module 1 along the guide portion 222 in the receiving portion 220. That is, the coupling portion 320 rotates around an axis extending in the y direction.

The coupling portion 320 that rotates along the guide portion 222 is received in the receiving portion 220 while having a bottom surface of the coupling portion 320 being in contact with the suspension threshold 224 as illustrated in (C) of FIG. 5. Accordingly, connection between the coupling portion 320 and the first solar cell module 1 is completed.

Here, as described above, the connection member 300 (see FIG. 3) includes the two coupling portions 320 that are connected via the connection portion 310 (see FIG. 3), and the two coupling portions 320 are concurrently (e.g., simultaneously) inserted into the first insertion hole 211 of the first solar cell module 1 and the second insertion hole 212 (see FIG. 1A) of the second solar cell module 2 (see FIG. 1A). Also, the connection portion 310 may be exposed to the outside between the first solar cell module 1 and the second solar cell module 2, and thus, the connection member 300 may be inserted into the first solar cell module 1 and the second solar cell module 2 by applying a force to the connection portion 310.

According to the current embodiment of the present invention, just by inserting the connection member 300 into the first insertion hole 211 and the second insertion hole 212 which are respectively formed in the first solar cell module 1 and the second solar cell module 2, the first solar cell module 1 and the adjacent second solar cell module 2 may be easily connected to each other, and aligned with each other.

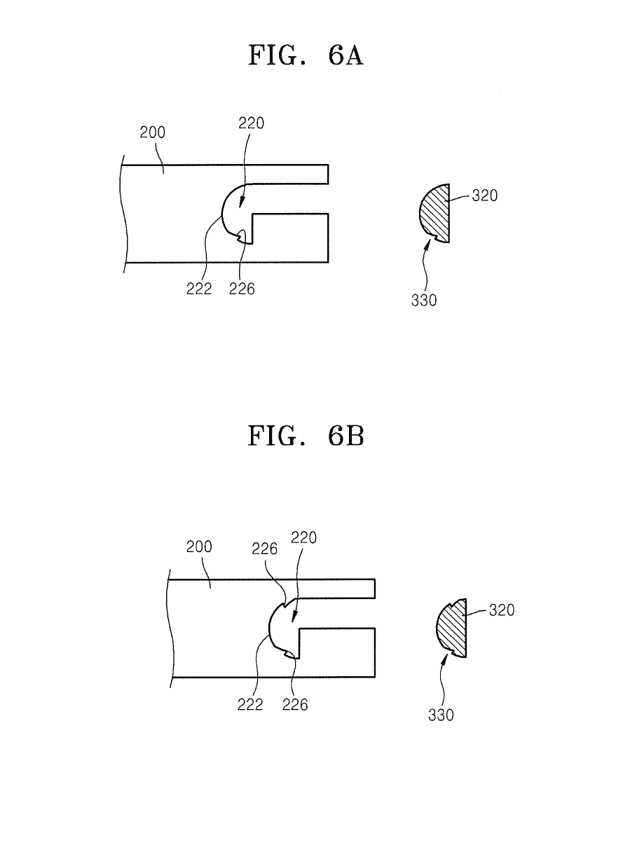

FIG. 6A is a modification example of a connecting structure of the solar cell modules of FIG. 1A according to an embodiment of the present invention.

Although FIG. 6A illustrates the coupling portion 320 that is received in the receiving portion 220 as illustrated in FIG. 5C, the coupling portion 320 and the receiving portion 220 are illustrated separately for convenience of description. Components such as the coupling portion 320, the receiving portion 220, the guide portion 222 or the like are substantially the same as those illustrated in and described with reference to FIGS. 3 through 5, and description below will focus on differences from the embodiment of FIG. 5.

Referring to FIG. 6A, a first connection portion 226 (e.g., a first securing part) may be formed in the guide portion 222, and a second connection portion 330 (e.g., a second securing part) that is coupled to the first connection portion 226 may be formed in the coupling portion 320. For example, the first connection portion 226 may be a protrusion, and the second connection portion 330 may be a groove that is matched by the protrusion.

In one embodiment, the first connection portion 226 may be protruded in a rotation direction of the coupling portion 320 from the guide portion 222, and may be elastic. Accordingly, the first connection portion 226 is pressed by a surface of the coupling portion 320 when the coupling portion 320 rotates while being in contact with the guide portion 222. When the coupling portion 320 is received in the receiving portion 220, the first connection portion 226 is restored to an original state by its elastic force, and is coupled to the second connection portion 330 formed in the coupling portion 320. Accordingly, when the coupling portion 320 is received in the receiving portion 220, separation of the coupling portion 320 from the frame 200 may be effectively prevented.

Although a single protrusion is illustrated as the first connection portion 226 in FIG. 6A, the embodiment of the present invention is not limited thereto, and the first connection portion 226 may also be at least two protrusions. (See FIG. 6B). Also, the first connection portion 226 may be a groove, and the second connection portion 330 may be a protrusion.

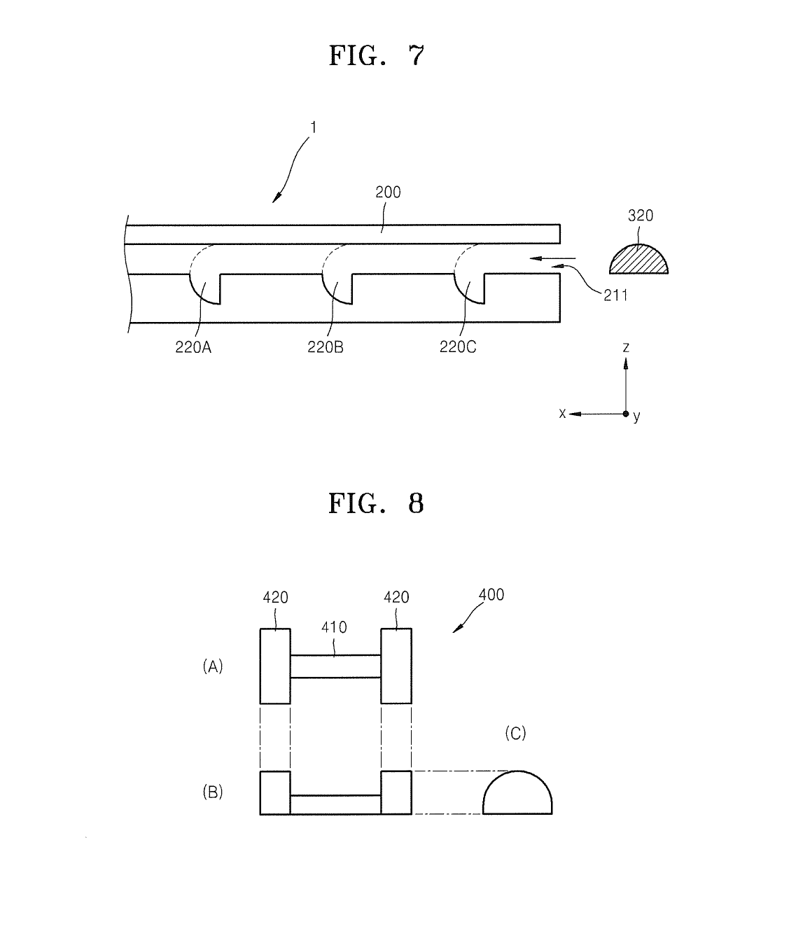

FIG. 7 is another modification example of a connecting structure of the solar cell modules of FIG. 1A according to an embodiment of the present invention.

FIG. 7 illustrates a state in which the coupling portion 320 is inserted into the first insertion hole 211 as illustrated in FIG. 5A. In FIG. 7, the frame 200, the coupling portion 320, and the first insertion hole 211 are substantially the same as those illustrated in and described with reference to FIGS. 1 through 5, and the description below will focus on differences from the previous embodiments.

Referring to FIG. 7, as the first insertion hole 211 is formed in the frame 200 along the first direction x of the first solar cell module 1, the first insertion hole 211 is connected in line with first through third receiving portions 220A through 220C.

While three receiving portions, e.g., the first receiving portion 220A, the second receiving portion 220B, and the third receiving portion 220C, are illustrated in FIG. 7, the number of receiving portions is not limited thereto.

A plurality of connection members 300 are sequentially inserted into the first insertion hole 211, and the coupling portions 320 are respectively received in the first receiving portion 220A, the second receiving portion 220B, and the third receiving portion 220C.

Thus, a connection force between the first solar cell module 1 and the second solar cell module 2 may be further improved or increased.

FIG. 8 illustrates a plan view (A), a front view (B), and a side view (C) of a connection member 400 according to an embodiment of the present invention. Referring to FIG. 8, the connection member 400 includes two coupling portions 420 and a connection portion 410 connecting the two coupling portions 420 to each other. The two coupling portions 420 each have a semi-cylindrical shape. A cross-section of the connection portion 410 may be rectangular, circular, or semicircle-shaped, but is not limited thereto.

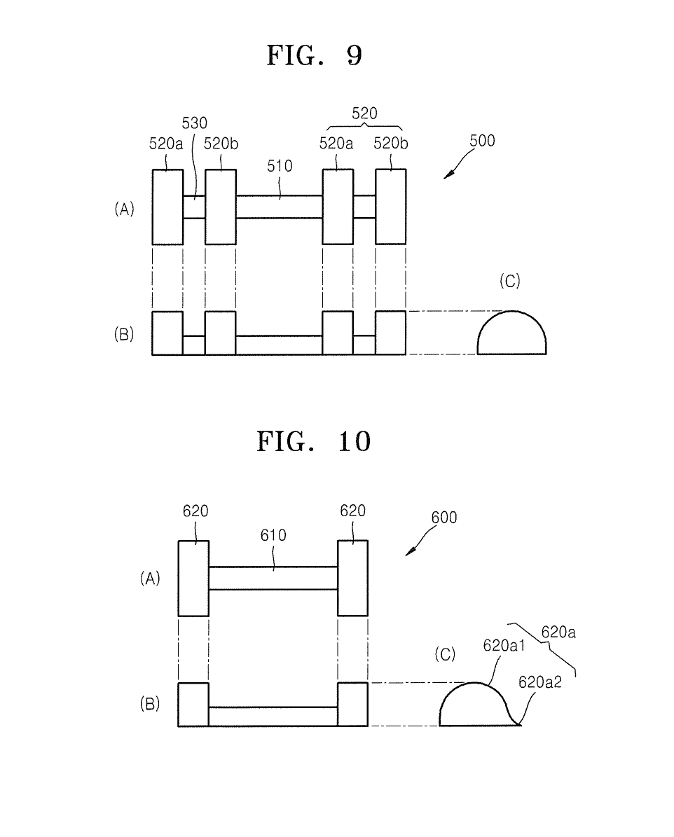

FIG. 9 illustrates a plan view (A), a front view (B), and a side view (C) of a connection member 500 according to an embodiment of the present invention. Referring to FIG. 9, the connection member 500 includes two coupling portions 520 and a connection portion 510 connecting the two coupling portions 520 to each other. The two coupling portions 520 each include two semi-cylindrical portions 520a and 520b spaced apart from each other in a first direction. The two semi-cylindrical portions are connected to each other by a connection member 530. Cross-sections of the connection portions 510 and 530 may be rectangular, circular, or semicircle-shaped, but is not limited thereto.

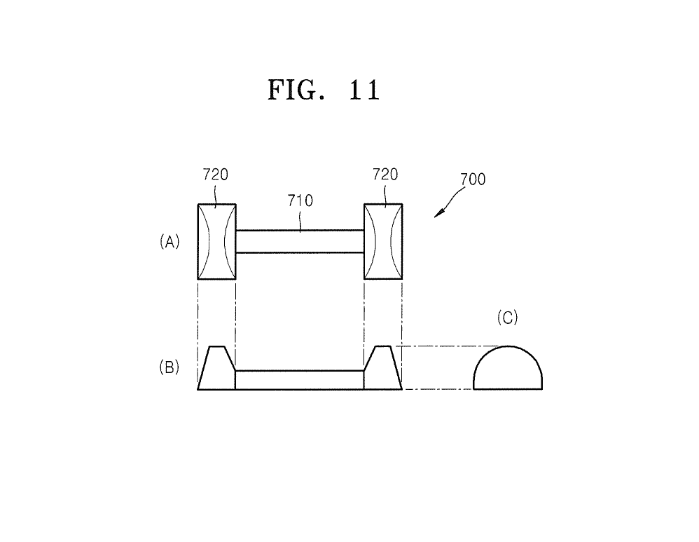

FIG. 10 illustrates a plan view (A), a front view (B), and a side view (C) of a connection member 600 according to an embodiment of the present invention. Referring to FIG. 10, the connection member 600 includes two coupling portions 620 and a connection portion 610 connecting the two coupling portions 620 to each other. Here, a cross-section of each of the coupling portions 620 has a curved side 620a and a substantially straight side 620b, and the curved side 620a includes at least first section 620a1 and second section 620a2 having different curvatures.

The first section 620a1 may be 25% to 50% of the surface of a semi-cylindrical portion of the same radius as the coupling portion, preferably 30% to 45%, more preferably 35% to 40%.

The second section 620a2 may be a flange. The flange is capable of fitting into corresponding section of a receiving portion and locking into place. The flange may be flexible and makes up the rest of the cross-section. The function of the flange is to improve the strength of the coupling between the coupling portion 620 and the receiving portion.

A cross-section of the connection portion 610 may be rectangular, circular, or semicircle-shaped, but is not limited thereto.

FIG. 11 illustrates a plan view (A), a front view (B), and a side view (C) of a connection member 700 according to an embodiment of the present invention. Referring to FIG. 11, the connection member 700 includes two coupling portions 720 and a connection portion 710 connecting the two coupling portions 720 to each other. Here, a cross section of each of the coupling portions 720 in a first direction has a tapered shape. A cross-section of the connection portion 710 may be rectangular, circular, or semicircle-shaped, but is not limited thereto.

The connecting structure of solar cell modules according to the embodiments of the present invention is not limited to the above-described structures and methods. Some or all of the embodiments may be selectively combined to make various modifications.

While the present invention has been particularly shown and described with reference to exemplary embodiments thereof, it will be understood by those of ordinary skill in the art that various changes in form and details may be made therein without departing from the spirit and scope of the present invention as defined by the following claims, and equivalents thereof.

### EXPLANATION OF SOME REFERENCE NUMERALS

| | |
|---|---|
| 1: first solar cell module | 2: second solar cell module |
| 100: solar cell unit | 200: frame |
| 211: first insertion hole | 212: second insertion hole |
| 220: receiving portion | 222: guide portion |
| 300: connection member | 310: connection portion |
| 320: coupling portion | |

What is claimed is:

1. A solar cell array comprising:
a plurality of solar cell modules, each of the solar cell modules comprising a frame having a first side extending along a first direction, and a first insertion hole formed in the first side and extending along the first direction; and
a connecting structure extending along a second direction perpendicular to the first direction for connecting two adjacent modules of the solar cell modules, and comprising a first coupling portion and a second coupling portion respectively received in the first insertion holes of the two adjacent modules,
wherein each of the first insertion holes has a guide portion and an insertion portion, the guide portion bending from the insertion portion to guide the first coupling portion and the second coupling portion into the respective guide portions.

2. The solar cell array of claim 1, wherein the connecting structure has a half dumbbell shape.

3. The solar cell array of claim 1, wherein each of the first coupling portion and the second coupling portion has a hemispheric shape.

4. The solar cell array of claim 1, wherein the connecting structure further comprises a middle portion connected between the first coupling portion and the second coupling portion of the connecting structure.

5. The solar cell array of claim 1, wherein the insertion portion extends along the first direction to the guide portion, and the guide portion has a larger width than that of the insertion portion in a third direction perpendicular to both the first direction and the second direction.

6. The solar cell array of claim 1, wherein the guide portion has a shape corresponding to the first coupling portion or the second coupling portion such that the connecting structure is rotatable in the guide portion.

7. The solar cell array of claim 1, wherein a side of the guide portion has a curvature substantially identical to that of the first coupling portion or the second coupling portion.

8. The solar cell array of claim 1, wherein a side of the guide portion comprises a first securing part configured to secure the first coupling portion or the second coupling portion in the corresponding guide portion.

9. The solar cell array of claim 8, wherein at least one of the first coupling portion or the second coupling portion comprises a second securing part configured to engage the first securing part.

10. The solar cell array of claim 9, wherein at least one of the first securing part or the second securing part is substantially elastic.

11. The solar cell array of claim 9, wherein one of the first securing part or the second securing part comprises a groove or step, and another one of the first securing part or the second securing part comprises a protrusion.

12. The solar cell array of claim 1, wherein the insertion portion comprises a plurality of insertion portions extending along the first direction, and the guide portion comprises a plurality of guide portions, the insertion portions and the guide portions being alternately arranged, and each of the guide portions has a larger width than that of a corresponding one of the insertion portions in a third direction perpendicular to both the first direction and the second direction.

13. The solar cell array of claim 1, wherein the frame further comprises a second side extending from an end of the first side in the second direction, and a portion of the first insertion hole extends into the second side in the second direction.

14. The solar cell array of claim 13, wherein a solar cell module of the plurality of solar cell modules further comprises a second insertion hole extending along the second side of the frame.

15. The solar cell array of claim 1, wherein the first insertion holes of the two adjacent modules face each other in the second direction and are substantially symmetrical in shape with respect to each other.

16. A connecting structure for connecting adjacent solar cell modules, comprising:
a first coupling portion;
a second coupling portion; and
a middle portion extending along a first direction and having a first end and a second end respectively connected to the first coupling portion and the second coupling portion,
wherein widths of the first coupling portion and the second coupling portion are wider than that of the middle portion in a second direction perpendicular to the first direction, and
wherein a cross-section of each of the first coupling portion and the second coupling portion has a curved side and a substantially straight side, the first direction being normal to the cross-section, and the connecting structure is configured to be rotatable around an axis extending along the first direction when the first coupling portion and the second coupling portion are respectively received in insertion holes of the adjacent solar cell modules.

17. The connecting structure of claim 16, wherein the connecting structure has a half dumbbell shape.

18. The connecting structure of claim 16, wherein each of the first coupling portion and the second coupling portion has a hemispheric shape.

19. The connecting structure of claim 16, wherein a cross-section of the middle portion has a rectangular, circular, or semi-circular shape.

20. The connecting structure of claim 16, wherein each of the first coupling portion and the second coupling portion has a shape corresponding to a guide portion of the insertion hole such that the connecting structure is rotatable in the guide portion around the axis extending along the first direction, while the connecting structure is not substantially rotatable in another portion of the insertion hole.

21. The connecting structure of claim 20, wherein the curved side has a curvature substantially identical to that of a side of the guide portion of the insertion hole.

22. The connecting structure of claim 20, wherein at least one of the first coupling portion or the second coupling portion comprises a first securing part configured to engage a second securing part on a side of the guide portion of the insertion hole.

23. The connecting structure of claim 22, wherein at least one of the first securing part or the second securing part is substantially elastic.

24. The connecting structure of claim 22, wherein one of the first securing part or the second securing part comprises a groove or step, and another one of the first securing part or the second securing part comprises a protrusion.

25. The connecting structure of claim 16, wherein each of the first coupling portion and the second coupling portion has a semi-cylindrical shape.

26. The connecting structure of claim 16, wherein each of the first coupling portion and the second coupling portion comprises two semi-cylindrical portions spaced apart from each other in the first direction.

27. The connecting structure of claim 16, wherein the curved side comprises at least two sections having different curvatures.

28. The connecting structure of claim 16, wherein a cross section of each of the first coupling portion and the second coupling portion in the first direction, has a tapered shape.
